(19) United States
(12) Patent Application Publication
(10) Pub. No.: US 2011/0065287 A1
(43) Pub. Date: Mar. 17, 2011

(54) PULSED CHEMICAL VAPOR DEPOSITION OF METAL-SILICON-CONTAINING FILMS

(75) Inventor: Cory Wajda, Sand Lake, NY (US)

(73) Assignee: TOKYO ELECTRON LIMITED, Tokyo (JP)

(21) Appl. No.: 12/557,771

(22) Filed: Sep. 11, 2009

(51) Int. Cl. H01L 21/314

(52) U.S. Cl. 438/785; 257/E21.269

(57) ABSTRACT

A method is provided for forming a metal-silicon-containing film on a substrate by pulsed chemical vapor deposition. The method includes providing the substrate in a process chamber, maintaining the substrate at a temperature suited for chemical vapor deposition of a metal-silicon-containing film by thermal decomposition of a metal-containing gas and a silicon-containing gas on the substrate, exposing the substrate to a continuous flow of the metal-containing gas, and during the continuous flow, exposing the substrate to sequential pulses of the silicon-containing gas.

### FIELD OF THE INVENTION

The present invention relates to semiconductor processing, and more particularly, to controlling silicon-content and silicon depth profile in metal-silicon-containing films deposited on a substrate.

### BACKGROUND OF THE INVENTION

In the semiconductor industry, the minimum feature sizes of microelectronic devices are approaching the deep sub-micron regime to meet the demand for faster, lower power microprocessors and digital circuits. Process development and integration issues are key challenges for new gate stack materials and silicide processing, with the imminent replacement of SiO₂ gate dielectric with high-permittivity (high-k) dielectric materials featuring a dielectric constant greater than that of SiO₂ (k˜3.9)), and the use of alternative gate electrode materials to replace doped poly-Si in sub-0.1 μm complimentary metal oxide semiconductor (CMOS) technology.

Downscaling of CMOS devices imposes scaling constraints on the gate dielectric material. The thickness of the standard SiO₂ gate oxide, is approaching the limit (˜1 nm) at which tunneling currents significantly impact transistor performance. To increase device reliability and reduce current leakage between the gate electrode to the transistor channel, semiconductor transistor technology is requiring the use of high-k gate dielectric materials that allow increased physical thickness of the gate oxide layer while maintaining an equivalent gate oxide thickness (EOT) of less than about 1.5 nm.

Metal-silicon-containing films may, for example, be deposited by chemical vapor deposition (CVD) or atomic layer deposition (ALD). The addition of silicon to metal-containing films generally decreases the dielectric constant (k) of these films and many applications therefore want to limit the amount of silicon in these films. Many advanced metal-silicon-containing films that have been proposed for gate dielectric applications can be very thin, for example between about 1 nm and about 10 nm. When depositing these very thin films in a semiconductor manufacturing environment, the film deposition rate must be low enough to enable good control and repeatability of the film thickness.

However, depositing metal-silicon-containing films with low silicon content, for example less that 20% silicon, has been problematic. Therefore, there is a need for new deposition methods for forming metal-silicon-containing films with low silicon-content, while providing good control over the silicon-content and silicon depth profile of the films.

### SUMMARY OF THE INVENTION

Some embodiments of the invention address problems associated with controlling silicon-content and silicon depth profile in advanced metal-silicon-containing films, for example thin metal silicate high-k films that may be used in current and future generations of high-k dielectric materials for use as a capacitor dielectric or as a gate dielectrics.

According to an embodiment of the invention, a method is provided for forming a metal-silicon-containing film on a substrate in a pulsed chemical vapor deposition process. The method includes providing the substrate in a process chamber, maintaining the substrate at a temperature suited for chemical vapor deposition of a metal-silicon-containing film by thermal decomposition of a metal-containing gas and a silicon-containing gas on the substrate, exposing the substrate to a continuous flow of the metal-containing gas, and during the continuous flow, exposing the substrate to sequential pulses of the silicon-containing gas.

According to some embodiments of the invention, the metal-silicon-containing film may be a metal silicate film such as a hafnium silicate film with a silicon-content less than 20% Si, less than 10% Si, or less than 5% Si.

### BRIEF DESCRIPTION OF THE DRAWINGS

In the accompanying drawings:

FIG. 1 is a schematic gas flow diagram for a pulsed deposition process for forming metal-silicon-containing films according to embodiments of the invention;

FIG. 2 is a schematic gas flow diagram for a pulsed deposition process for forming metal-silicon-containing films according to embodiments of the invention

FIG. 3 schematically shows pulsed gas flows for a silicon-containing gas during a pulsed deposition process for forming metal-silicon-containing films according to embodiments of the invention;

FIG. 4 schematically shows pulsed gas flows for a silicon-containing gas during a pulsed deposition process for forming metal-silicon-containing films according to embodiments of the invention;

FIG. 5 is a process flow diagram of one embodiment of the method of forming a metal-silicon-containing film on a substrate;

FIGS. 6A-6B show schematic cross-sectional views for forming a films structure containing a metal-silicon-containing film according to one embodiment of the invention;

FIGS. 7A-7C show schematic cross-sectional views for forming a film structure containing a metal-silicon-containing film according to one embodiment of the invention;

FIGS. 8A and 8B show simplified block diagrams of pulsed CVD systems for depositing metal-silicon-containing films on a substrate according to embodiments of the invention;

FIG. 9A shows silicon-content in CVD and pulsed CVD hafnium silicate films as a function of Hf(Ot-Bu)₄ gas flow according to embodiments of the invention; and

FIG. 9B shows silicon-content in CVD and pulsed CVD hafnium silicate films as a function of index of refraction according to embodiments of the invention.

### DETAILED DESCRIPTION OF SEVERAL EMBODIMENTS OF THE INVENTION

Embodiments of the invention provide a method for depositing metal-silicon-containing films on a substrate by a pulsed chemical vapor deposition process. The metal-silicon-containing films can include metal-silicon-containing oxides, nitrides, and oxynitrides of Group II, Group IlIl elements (e.g., hafnium and zirconium), or rare earth elements of the Periodic Table of the Elements, or a combination thereof. The metal-silicon-containing films may be utilized in advanced semiconductor devices and can have a thickness between about 1 nm and about 10 nm, or between about 1 nm and about 5 nm. In some examples, metal-silicon-containing high-k gate dielectric films may have a thickness between about 1 nm and about 3 nm, for example about 2 nm.

During a conventional CVD process, silicon-content and silicon depth profiles of metal-silicon-containing films have been controlled by selecting a gas flow rate of a metal-containing gas, a gas flow rate of a silicon-containing gas, or both. In order to deposit metal-silicon-containing films with low silicon content, a continuous flow of the metal-containing gas may be increased and/or a continuous flow of the silicon-containing gas may be reduced during the film deposition process. However, increasing the continuous flow of the metal-containing gas results in increased film deposition rate for CVD processes that are operated in mass transport limited regime, thereby reducing the deposition time, in some examples down to a few seconds where control over the film thickness is poor. Furthermore, there are numerous problems associated with using a very low gas flow rate of a silicon-containing gas during a conventional CVD process to obtain metal-silicon-containing films with low silicon-content, for example silicon content-below 20% Si, or below 10% Si. The use of very low gas flow rates of a silicon-containing gas can be limited by the available flow control equipment and may result in poor distribution of the silicon-containing gas in the deposition chamber and non-uniform film deposition.

The inventors have realized that maintaining a continuous flow of a metal-containing gas while pulsing a silicon-containing gas during pulsed chemical vapor deposition of metal-silicon-containing films provides reliable means for achieving low silicon-content and tailoring the silicon depth profile of these films for advanced electronic applications.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Furthermore, it is understood that the various embodiments shown in the figures are illustrative representations and are not necessary drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention.

Embodiments of the invention utilize pulsed CVD processing to control silicon-content and silicon depth profile in metal-silicon-containing films. The inventive pulsing of a silicon-containing gas while continuously flowing a metal-containing gas and optionally an oxidizer gas allows for depositing metal-silicon-containing films with tunable low silicon-content that is lower than can be achieved using conventional CVD processing. According to embodiments of the invention, the substrate is maintained at a temperature that enables CVD processing using a metal-containing gas and a silicon-containing gas. Thus, the substrate is maintained at a temperature that is higher than may be used for ALD processing when using the metal-containing gas, the silicon-containing gas, or both. Pulsed CVD processing can have several advantages over ALD, including excellent film quality due to the higher temperature and higher throughput due to higher deposition rates.

Hafnium (Hf) and zirconium(Zr) compounds have received considerable attention as high-k materials for integrated circuit applications, for example as gate dielectrics in MOS transistors. Oxides of both elements (HfO₂, ZrO₂) have high dielectric constants (k˜25) and can form silicate phases (HfSiO, ZrSiO) that are stable in contact with a silicon substrate at conventional temperatures used for manufacturing integrated circuits. Material properties of hafnium silicate high-k films (e.g., dielectric constant (k) and index of refraction (n)) depend on the silicon-content of the films in addition to the processing conditions used, including film deposition conditions and any post-treatment conditions. For example, increasing the silicon-content of HfSiO films lowers the index of refraction of the films.

Furthermore, doping of HfO₂ and ZrO₂ films with low amounts of Si (e.g., below about 20% Si) to form HfSiO and ZrSiO films can result in the tetragonal phase to be more energetically favorable than the monoclinic phase that is present at ambient conditions. The stabilization of the tetragonal phase increases the dielectric constant k significantly, for example from about 17 for HfO₂ to about 34 for HfSiO, and from about 20 for ZrO₂ to about 42 for ZrSiO, at Si doping levels of 12.5% Si. The increased k values for HfSiO and ZrSiO films allows for increasing the physical thickness of these films and greatly reducing leakage current while obtaining the same equivalent oxide thickness (EOT) as the corresponding HfO₂ and ZrO₂films.

In the following description, deposition of hafnium silicate (HfSiO) films is described but those skilled in the art will readily appreciate that teachings of the embodiments of the invention may be applied to deposit a variety of different metal-silicon-containing films containing oxides, nitrides, and oxynitrides of Group II elements, Group IlIl elements, and rare earth elements of the Periodic Table of the Elements, and mixtures thereof.

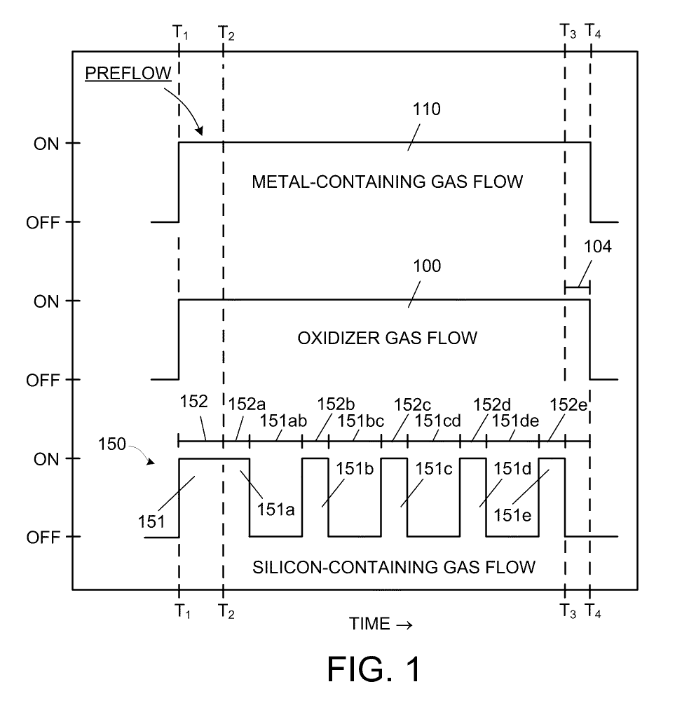

FIG. 1 is a schematic gas flow diagram for a pulsed deposition process for forming metal-silicon-containing films according to embodiments of the invention. The gas flow diagram schematically shows metal-containing gas flow 110 and pulsed silicon-containing gas flow 150. The gas flow diagram further shows oxidizer gas flow 100 that may be omitted in some embodiments of the invention. The oxidizer gas flow 100 may contain an oxygen-containing gas, a nitrogen-containing gas, or a oxygen- and nitrogen-containing gas. In one example, a hafnium silicate film may be deposited on a substrate using a metal-containing gas flow 110 containing Hf(Ot-Bu)₄ (hafnium tert-butoxide, HTB) gas, silicon-containing gas flow 150 containing Si(OCH₂CH₃)₄ (tetraethoxysilane, TEOS), and an oxidizer gas flow 100 containing O₂. The gas flow diagram in FIG. 1 includes preflow 151 and a preflow period 152 from time T₁ to time T₂, where the gas flows are stabilized before exposure to a substrate in a process chamber. During the preflow period 152, the gas flows 110, and 150 bypass the process chamber and are not exposed to the substrate. However, oxidizer gas flow 100 may be flowed through the process chamber during the preflow period 152.

Following the preflow period 152, starting at time T₂, a substrate is exposed to gas flows 100, 110 and 150 in a process chamber to deposit a metal-silicon-containing film on the substrate. Exposure of the substrate to the metal-containing gas, the oxidizer gas, and the silicon-containing gas, starts at time T₂, and from time T₂ to T₃ the substrate is continuously exposed to metal-containing gas flow 110 and oxidizer gas flow 100, and gas pulses 151a-151e of the silicon-containing gas flow 150. According to the embodiment depicted in FIG. 1, pulse lengths 152a-152e for gas pulses 151a-151e, respectively, can be equal or substantially equal. Exemplary pulse lengths 152a-152e can range from about 1 sec to about 20 sec, from about 2 sec to about 10 sec, or from about 5 sec to about 10 sec.

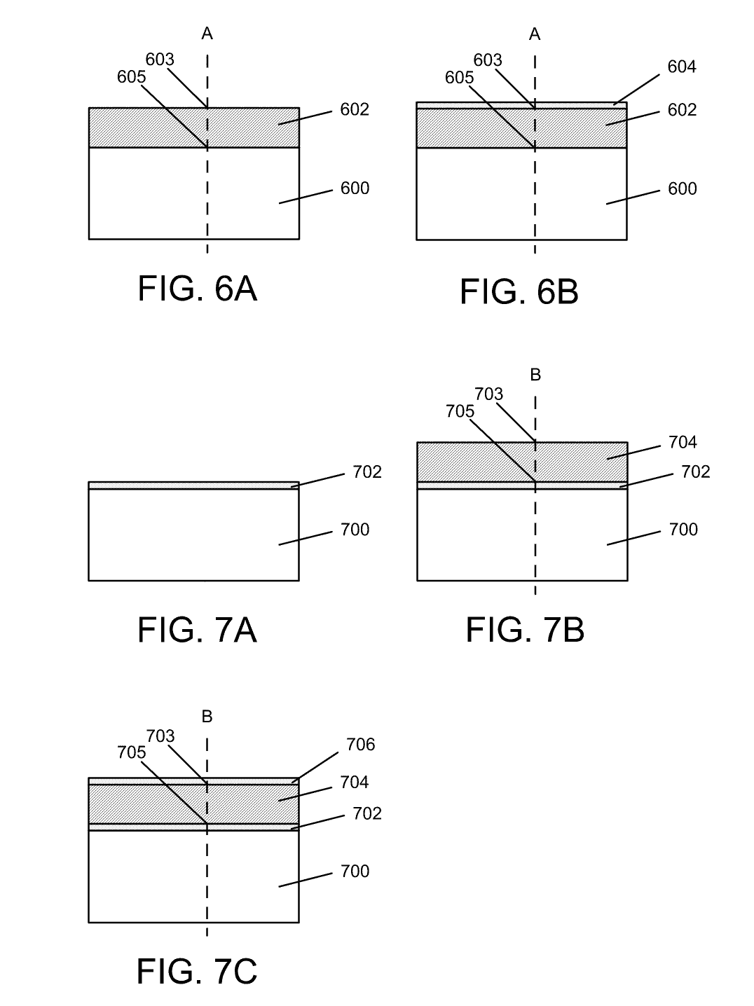

Furthermore, according to the embodiment depicted in FIG. 1, pulse delay 151ab between gas pulses 151a and 151b, pulse delay 151bc between gas pulses 151b and 151c, pulse delay 151cd between gas pulses 151c and 151d, and pulse delay 151de between gas pulses 151d and 151e, can be the same or substantially the same. Exemplary pulse delays 151ab-151de can range from about 1 sec to about 20 sec, from about 2 sec to about 10 sec, or from about 5 sec to about 10 sec. Referring also to FIG. 6A, according to an embodiment of the invention, equal or substantially equal pulse lengths 152a-152e and equal or substantially equal pulse delays 151ab-151de may be used to deposit a metal-silicon-containing film (e.g., a HfSiO film) with substantially uniform silicon-content along line “A” from an external surface 603 of the metal-silicon-containing film 602 to an interface 605 between the metal-silicon-containing film 602 and the substrate 600.

FIG. 1 further shows a time interval 104 between times T₃ and T₄ where the substrate is not exposed to the silicon-containing gas but the substrate is exposed to the metal-containing gas flow 110 and the oxidizer gas flow 100. The length of the time interval 104 may be tailored to deposit a metal-containing cap layer 604 (e.g., HfO₂) with a desired thickness on the metal-silicon-containing film 602, where the metal-containing cap layer 604 does not contain silicon. This is schematically shown in FIG. 6B. In some examples, the metal-containing cap layer 604 may have a thickness between about 0.5 nm and about 10 nm, or between about 1 nm and about 5 nm. In another example, T₄ may be same as T₃ and deposition of the metal-containing cap layer 604 is therefore omitted.

Although five silicon-containing gas pulses 151a-151e are shown in FIG. 1, embodiments of the invention contemplate the use of any number of silicon-containing gas pulses, for example between 1 and 100 pulses, between 1 and 50 pulses, between 1 and 20 pulses, or between 1 and 10 pulses.

According to some embodiments, the silicon-containing gas may contain a molecular silicon-oxygen-containing gas where the gas molecules contain both silicon and oxygen. Examples of molecular silicon-oxygen-containing gases include the chemical family of Si(OR)₄, where R is a methyl group or an ethyl group. According to some embodiments, the oxidizer gas flow 100 may be omitted when a molecular silicon-oxygen-containing gas is utilized. Furthermore, the oxidizer gas flow 100 may be omitted when the metal-containing gas contains oxygen. In another example, the oxidizer gas flow 100 may be omitted when the metal-containing gas contains oxygen and a molecular silicon-oxygen-containing gas is used.

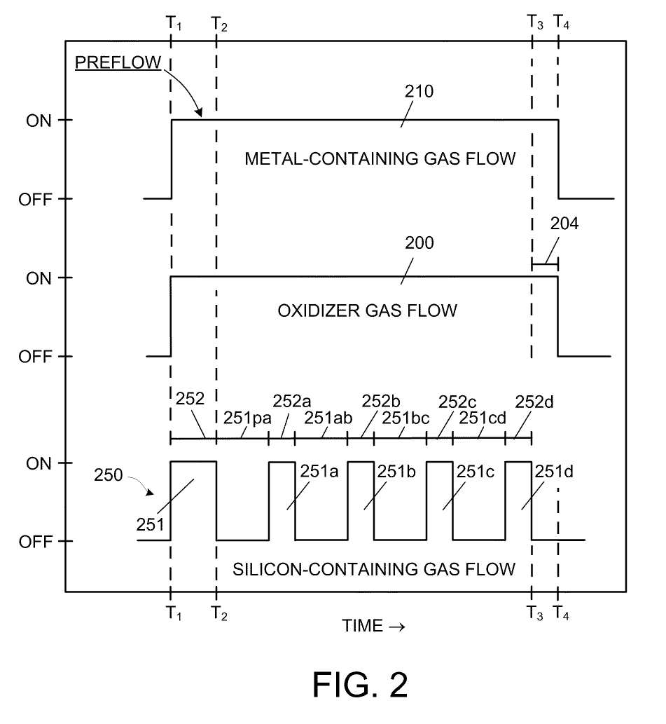

FIG. 2 is a schematic gas flow diagram for a pulsed deposition process for forming metal-silicon-containing films according to embodiments of the invention. The gas flow diagram in FIG. 2 is similar to the gas flow diagram in FIG. 1 and schematically shows metal-containing gas flow 210 and silicon-containing gas flow 250. The gas flow diagram further shows optional oxidizer gas flow 200 that may be omitted in some embodiments of the invention. The gas flow diagram in FIG. 2 includes preflow 251 and a preflow period 252 from time T₁ to time T₂, where the gas flows 210 and 250 are stabilized before exposure to a substrate in a process chamber. However, oxidizer gas flow 200 may be flowed through the process chamber during the preflow period 252.

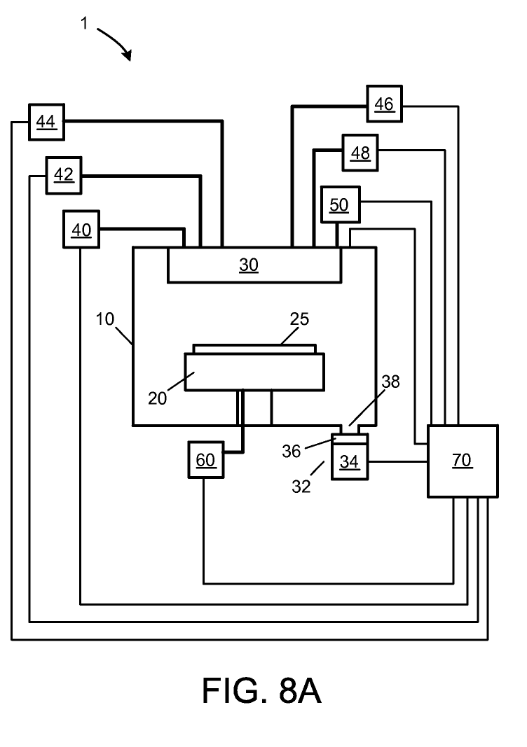

Following the preflow period 252, starting at time T₂ and during pulse delay 251pa, the substrate is continuously exposed to gas flows 110 and 100 but the substrate is not exposed to the silicon-containing gas. During pulse delay 251pa, a metal-containing interface layer 702 (e.g., HfO₂) with a desired thickness is deposited on the substrate 700, where the metal-containing interface layer 702 does not contain silicon. This is schematically shown in FIG. 7A. In some examples, the metal-containing interface layer 702 may have a thickness between about 0.5 nm and about 10 nm, or between about 1 nm and about 5 nm.

After the pulse delay 251 pa, the substrate is continuously exposed to metal-containing gas flow 210, oxidizer gas flow 100, and gas pulses 251a-251d of the silicon-containing gas flow 250 to deposit a metal-silicon-containing film 704 (e.g., HfSiO) on the metal-containing interface layer 702. According to the embodiment depicted in FIG. 2, pulse lengths 252a-252d for gas pulses 251a-251e, respectively, can be equal or substantially equal. Exemplary pulse lengths 252a-252d can range from about 1 sec to about 20 sec, from about 2 sec to about 10 sec, or from about 5 sec to about 10 sec. Furthermore, according to the embodiment depicted in FIG. 2, pulse delay 215pa, pulse delay 251ab between gas pulses 251a and 251b, pulse delay 251bc between gas pulses 251b and 251c, and pulse delay 251cd between gas pulses 251c and 251d, can be equal or substantially equal. Exemplary pulse delays 251pa, 251ab-251cd can range from about 1 sec to about 20 sec, from about 2 sec to about 10 sec, or from about 5 sec to about 10 sec. According to the embodiment shown in FIG. 2, equal or substantially equal pulse lengths 252a-252d and pulse delays 251pa, and 251ab-251cd may be used.

Referring also to FIG. 7B, according to an embodiment of the invention, equal or substantially equal pulse lengths 252a-252d and equal or substantially equal pulse delays 251pa and 251ab-251cd may be used to deposit a metal-silicon-containing film (e.g., a HfSiO films) with substantially uniform silicon-content along line “B” from an external surface 703 of the metal-silicon-containing film 704 to interface 705 between the metal-silicon-containing film 704 and the metal-containing interface layer 702.

FIG. 2 further shows a time interval 204 between times T₃ and T₄ where the substrate is not exposed to the silicon-containing gas but the substrate is exposed to the metal-containing gas flow 210 and the oxidizer gas flow 200. The length of the time interval 204 may be tailored to deposit a metal-containing cap layer 706 (e.g., HfO₂) with a desired thickness on the metal-silicon-containing film 704, where the metal-containing cap layer 706 does not contain silicon. This is schematically shown in FIG. 7C. In some examples, the metal-containing cap layer 706 may have a thickness between about 0.5 nm and about 10 nm, or between about 1 nm and about 5 nm. In one example, T₄ may be same as T₃ and deposition of a metal-containing cap layer 706 therefore omitted.

Although four silicon-containing gas pulses 251a-d51d are shown in FIG. 2, embodiments of the invention contemplate the use of any number of silicon-containing gas pulses, for example between 1 and 100 pulses, between 1 and 50 pulses, between 1 and 20 pulses, or between 1 and 10 pulses.

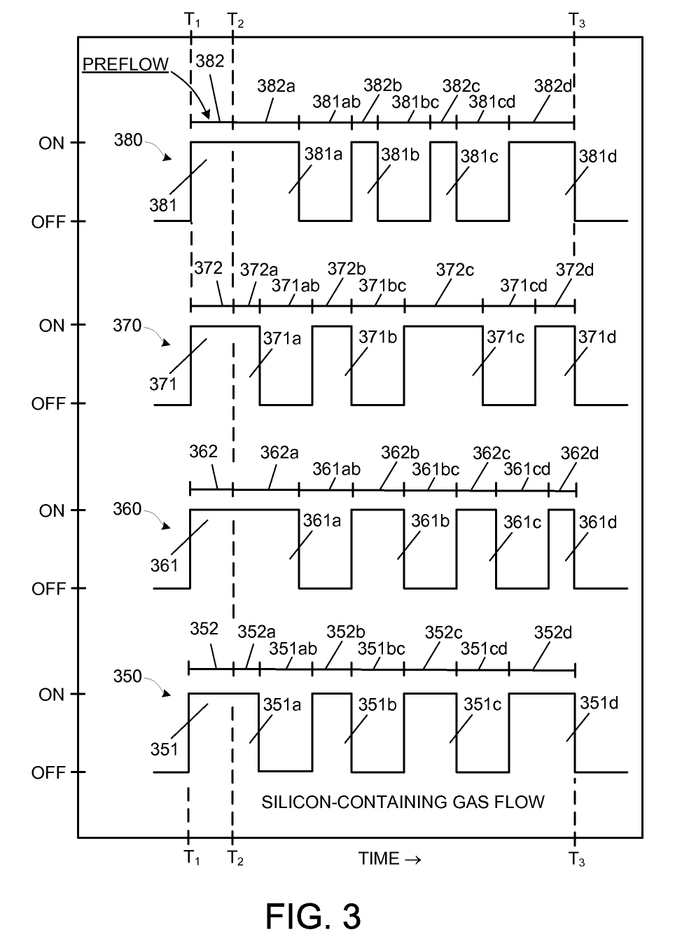

FIG. 3 schematically shows gas flows 350-380 for a silicon-containing gas during a pulsed deposition process for forming metal-silicon-containing films according to embodiments of the invention. The silicon-containing gas flow 350 includes preflow period 351 from time T₁ to time T₂, where the gas flows are stabilized before exposure to a substrate in a process chamber.

Still referring to FIG. 3, during metal-silicon-containing film deposition from time T₂ to T₃, the substrate is continuously exposed to a metal-containing gas flow (not shown), an oxidizer gas flow (not shown), and gas pulses 351a-351d of silicon-containing gas flow 350. According to the embodiment depicted in FIG. 3, pulse lengths 352a-352d monotonically increase for gas pulses 351a-351d, respectively. Exemplary pulse lengths 352a-352d can range from about 1 sec to about 20 sec, from about 2 sec to about 10 sec, or from about 5 sec to about 10 sec. Furthermore, pulse delay 351ab between gas pulses 351a and 351b, pulse delay 351bc between gas pulses 351b and 351c, and pulse delay 351cd between gas pulses 351c and 351d, can be the same or substantially the same. However, equal pulse delays are not required for embodiments of the invention and different pulse delays may be used. Exemplary pulse delays 351ab-351cd can range from about 1 sec to about 20 sec, from about 2 sec to about 10 sec, or from about 5 sec to about 10 sec. Referring also to FIG. 6, the use of monotonically increasing pulse lengths 352a-352d may be used to deposit a metal-silicon-containing film (e.g., a HfSiO film) with increasing silicon-content along line “A” from an external surface 603 of the metal-silicon-containing film 602 to an interface 605 between the metal-silicon-containing film 602 and the substrate 600.

According to another embodiment depicted in FIG. 3, a silicon-containing gas flow 360 includes a preflow period 361 from time T₁ to time T₂, where the gas flows are stabilized before exposure to a substrate in a process chamber. During metal-silicon-containing film deposition from time T₂ to T₃, the substrate is continuously exposed to a metal-containing gas flow (not shown), an oxidizer gas flow (not shown), and gas pulses 361a-361d of silicon-containing gas flow 360. According to the embodiment depicted in FIG. 3, pulse lengths 352a-352d monotonically decrease for gas pulses 361a-361d, respectively.

Exemplary pulse lengths 362a-362d can range from about 1 sec to about 20 sec, from about 2 sec to about 10 sec, or from about 5 sec to about 10 sec. Furthermore, according to the embodiment depicted in FIG. 3, pulse delay 361ab between gas pulses 361a and 361b, pulse delay 361bc between gas pulses 361b and 361c, and pulse delay 361cd between gas pulses 361c and 361d, can be the same or substantially the same. However, equal pulse delays are not required for embodiments of the invention and different pulse delays may be used. Exemplary pulse delays 361ab-361cd can range from about 1 sec to about 20 sec, from about 2 sec to about 10 sec, or from about 5 sec to about 10 sec. The use of monotonically decreasing pulse lengths 362a-362d may be used to deposit a metal-silicon-containing film (e.g., a HfSiO film) with decreasing silicon-content along line “A” from an external surface of the 603 of the metal-silicon-containing film 602 to an interface 605 between the metal-silicon-containing film 602 and the substrate 600.

According to another embodiment depicted in FIG. 3, a silicon-containing gas flow 370 includes preflow period 371 from time T₁ to time T₂, where the gas flows are stabilized before exposure to a substrate in a process chamber. During metal-silicon-containing film deposition from time T₂ to T₃ using silicon-containing gas flow 370, the substrate is continuously exposed to a metal-containing gas flow (not shown) an oxidizer gas flow (not shown), and gas pulses 371a-371d of silicon-containing gas flow 370. According to the embodiment depicted in FIG. 3, the pulse lengths 372a-372b vary as 372a<372b<372c>372d. Exemplary pulse lengths 372a-372d can range from about 1 sec to about 20 sec, from about 2 sec to about 10 sec, or from about 5 sec to about 10 sec. Furthermore, according to the embodiment depicted in FIG. 3, pulse delay 371ab between gas pulses 371a and 371b, pulse delay 371bc between gas pulses 371b and 371c, and pulse delay 371cd between gas pulses 371c and 371d, can be the same or substantially the same. However, equal pulse delays are not required for embodiments of the invention and different pulse delays may be used. Exemplary pulse delays 371ab-371cd can range from about 1 sec to about 20 sec, from about 2 sec to about 10 sec, or from about 5 sec to about 10 sec.

The use of a relatively long pulse length 372c and shorter pulse lengths 372a, 372b and 372d may be used to deposit a metal-silicon oxide film (e.g., a HfSiO film) having a lower silicon-content near the external surface 603, and near the interface 605 between the metal-silicon-containing film 602 and the substrate 600, and a higher silicon-content along line “A” near the middle of the metal-silicon-containing film 602.

According to another embodiment depicted in FIG. 3, a silicon-containing gas flow 380 includes a preflow period 381 from time T₁ to time T₂, where the gas flows are stabilized before exposure to a substrate in a process chamber. During metal-silicon-containing film deposition from time T₂ to T₃ using silicon-containing gas flow 380, the substrate is continuously exposed to a metal-containing gas flow (not shown) an oxidizer gas flow (not shown), and gas pulses 381a-381d of silicon-containing gas flow 370. According to the embodiment depicted in FIG. 3, the pulse lengths 382a-382d vary as 382a>382b=382c<382d. Exemplary pulse lengths 382a-382d can range from about 1 sec to about 20 sec, from about 2 sec to about 10 sec, or from about 5 sec to about 10 sec. Furthermore, according to the embodiment depicted in FIG. 3, pulse delay 381ab between gas pulses 381a and 381b, pulse delay 381bc between gas pulses 381b and 371c, and pulse delay 381cd between gas pulses 381c and 381d, can be the same or substantially the same. However, equal pulse delays are not required for embodiments of the invention and different pulse delays may be used. Exemplary pulse delays 381ab-381cd can range from about 1 sec to about 20 sec, from about 2 sec to about 10 sec, or from about 5 sec to about 10 sec.

The use of a relatively long pulse lengths 382a and 382d and shorter pulse lengths 382b and 382c may be used to deposit a metal-silicon oxide film (e.g., a HfSiO film) with a higher silicon-content near the external surface 603 and the interface 605 between the metal-silicon-containing film 602 and the substrate 600, and a lower silicon-content along line “A” near the middle of the metal-silicon-containing film 602.

As those skilled in the art will readily recognize, any of the silicon-containing gas flows 350-380 may be modified to further include a pulse delay between a preflow and a first pulse of a silicon-containing gas to deposit a metal-containing interface layer on the substrate prior to depositing a metal-oxygen-containing layer, as described above and shown in FIGS. 2 and 7. Furthermore, a metal-containing oxide cap layer may be deposited on the metal-silicon-containing film between times T₃ and T₄ where the substrate is not exposed to the silicon-containing gas but the substrate is exposed to the metal-containing gas flow and the oxidizer gas flow, as shown in FIGS. 1, 2, and 7.

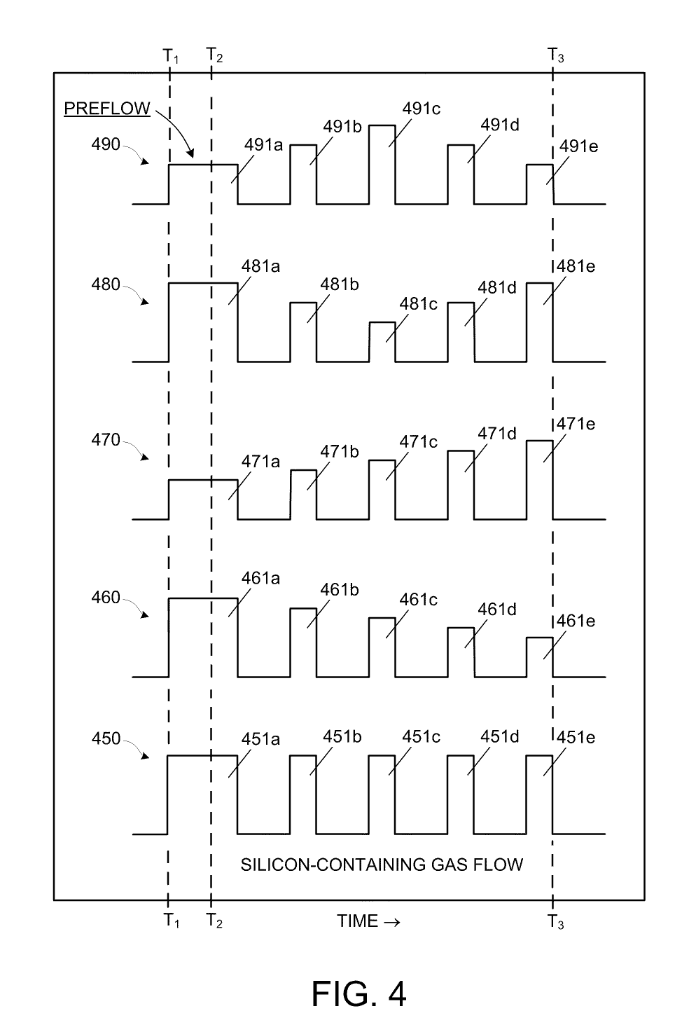

FIG. 4 schematically shows gas flows 450-490 for a silicon-containing gas during a pulsed deposition process for forming metal-silicon-containing films according to embodiments of the invention. The silicon-containing gas flow 150 from FIG. 1 is reproduced as silicon-containing gas flow 450 in FIG. 4. For simplicity, only silicon-containing gas pulses and preflow periods are shown in FIG. 4. Silicon-containing gas flows 460-480 are similar to the silicon-containing gas flow 450 but differ in some pulse intensities, i.e., gas flow rates of the silicon-containing gas can differ in one or more silicon-containing gas pulses. The silicon-containing gas flow 460 includes gas pulses 461a-461e that monotonically increase in intensity from pulse 461a to pulse 461e, while the pulse lengths and pulse delays are the same or substantially the same. Referring also to FIG. 6, the silicon-containing gas flow 461 of may be used to deposit a metal-silicon oxide film with increasing silicon-content along line “A” from an external surface of the 603 of the metal-silicon-containing film 602 to an interface 605 between the metal-silicon-containing film 602 and the substrate 600.

The silicon-containing gas flow 470 includes gas pulses 471a-471e that monotonically decrease in intensity from gas pulse to 471e, while the pulse lengths and pulse delays are the same or substantially the same. The silicon-containing gas flow 470 of may be used to deposit a metal-silicon-containing film 602 with decreasing silicon-content along line “A” from an external surface of the 603 of the metal-silicon-containing film 602 to an interface 605 between the metal-silicon-containing film 602 and the substrate 600.

The silicon-containing gas flow 480 includes gas pulses 481a-481e that decrease in intensity from gas pulse 481a to gas pulse 481c and then increase in intensity from gas pulse 481c to gas pulse 481e, while the pulse length and pulse delays are the same or substantially the same. The silicon-containing gas flow 480 of may be used to deposit a metal-silicon oxide film (e.g., a HfSiO film) with a higher silicon-content near the external surface 603 and near the interface 605 between the metal-silicon-containing film 602 and the substrate 600, and a lower silicon-content along line “A” near the middle of the metal-silicon-containing film 602.

The silicon-containing gas flow 490 includes gas pulses 491a-491e that increase in intensity from gas pulse to gas pulse 491c and then decrease in intensity from gas pulse 491c to pulse 4981e, while the pulse lengths and pulse delays are the same or substantially the same. The silicon-containing gas flow 490 of may be used to deposit a metal-silicon-containing film (e.g., a HfSiO film) with a lower silicon-content near the external surface 603 and near the interface 605 between the metal-silicon-containing film 602 and the substrate 600, and with a higher silicon-content along line “A” near the middle of the metal-silicon-containing film 602.

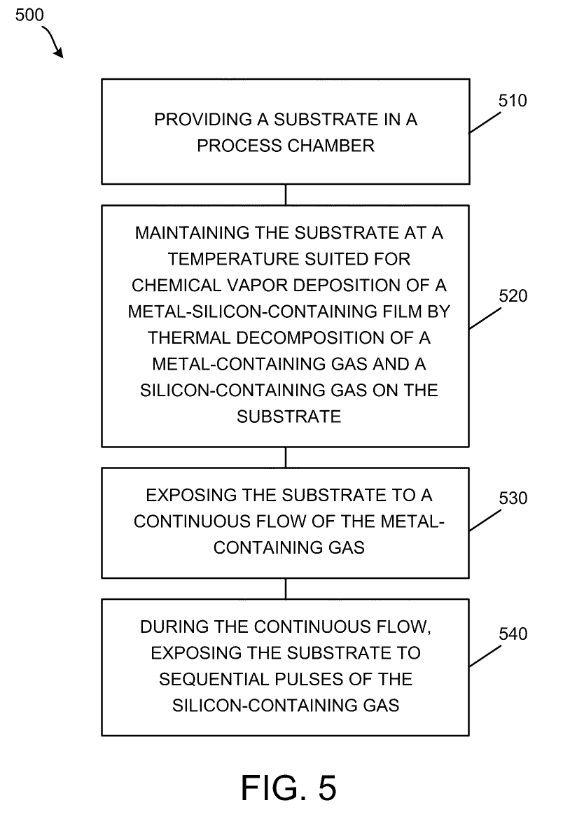

FIG. 5 is a process flow diagram of one embodiment of the method of forming a metal-silicon-containing film on a substrate. The process flow 500 includes, in 510, providing a substrate in a process chamber. In 520, the substrate is maintained at a temperature suited for chemical vapor deposition of a metal-silicon-containing film by thermal decomposition of a metal-containing gas and a silicon-containing gas on the substrate. In 530, the substrate is exposed to a continuous flow of the metal-containing gas, and, in 540, during the continuous flow, the substrate is exposed to sequential pulses of the silicon containing gas. According to one embodiment, the continuous flow further comprises an oxidizer gas.

According to one embodiment, the metal-containing gas is exposed to the substrate without interruption from a period of time before a first pulse of the silicon-containing gas. According to another embodiment, the metal-containing gas is exposed to the substrate without interruption from a period of time after a last pulse of the silicon-containing gas. According to yet another embodiment, the metal-containing gas is exposed to the substrate without interruption from a period of time before a first pulse of the silicon-containing gas to a period of time after a last pulse of the silicon-containing gas.

According to one embodiment, a gas flow rate is substantially the same in the each of the sequential pulses of the silicon-containing gas. According to another embodiment, a gas flow rate of the silicon-containing gas increases in consecutive pulses. According to yet another embodiment, a gas flow rate of the silicon-containing gas decreases in consecutive pulses. According to still another embodiment, a gas flow rate of the silicon-containing gas pulses increases in consecutive pulses and thereafter the gas flow rate of the silicon-containing gas decreases in consecutive pulses. According to an embodiment, a gas flow rate of the silicon-containing gas pulses decreases in consecutive pulses and thereafter the gas flow rate of the silicon-containing gas increases in consecutive pulses.

According to one embodiment, the metal-containing gas comprises a Group II precursor, a Group IlIl precursor, or a rare earth precursor, or a combination thereof. According to another embodiment, the metal-containing gas comprises a hafnium-precursor, a zirconium-precursor, or both a hafnium-precursor and a zirconium-precursor, in order to deposit a hafnium silicate film, a zirconium silicate film, or a hafnium zirconium silicate film.

Embodiments of the inventions may utilize a wide variety of different Group II alkaline earth precursors. For example, many alkaline earth precursors have the formula:

ML¹L²Dₓ

where M is an alkaline earth metal element selected from the group of beryllium (Be), magnesium (Mg), calcium (Ca), strontium (Sr), and barium (Ba). L¹ and L² are individual anionic ligands, and D is a neutral donor ligand where x can be 0, 1, 2, or 3. Each L¹, L² ligand may be individually selected from the groups of alkoxides, halides, aryloxides, amides, cyclopentadienyls, alkyls, silyls, amidinates, β-diketonates, ketoiminates, silanoates, and carboxylates. D ligands may be selected from groups of ethers, furans, pyridines, pyroles, pyrolidines, amines, crown ethers, glymes, and nitriles.

Examples of L group alkoxides include tert-butoxide, iso-propoxide, ethoxide, 1-methoxy-2,2-dimethyl-2-propionate (mmp), 1-dimethylamino-2,2′-dimethyl-propionate, amyloxide, and neo-pentoxide. Examples of halides include fluoride, chloride, iodide, and bromide. Examples of aryloxides include phenoxide and 2,4,6-trimethylphenoxide. Examples of amides include bis(trimethylsilyl)amide di-tert-butylamide, and 2,2,6,6-tetramethylpiperidide (TMPD). Examples of cyclopentadienyls include cyclopentadienyl, 1-methylcyclopentadienyl, 1,2,3,4-tetramethylcyclopentadienyl, 1-ethylcyclopentadienyl, pentamethylcyclopentadienyl, 1-iso-propylcyclopentadienyl, 1-n-propylcyclopentadienyl, and 1-n-butylcyclopentadienyl. Examples of alkyls include bis(trimethylsilyl)methyl, tris(trimethylsilyl)methyl, and trimethylsilylmethyl. An example of a silyl is trimethylsilyl. Examples of amidinates include N,N′-di-tert-butylacetamidinate, N,N′-di-iso-propylacetamidinate, N,N′-di-isopropyl-2-tert-butylamidinate, and N,N′-di-tert-butyl-2-tert-butylamidinate. Examples of β-diketonates include 2,2,6,6-tetramethyl-3,5-heptanedionate (THD), hexafluoro-2,4-pentanedionate (hfac), and 6,6,7,7,8,8,8-heptafluoro-2,2-dimethyl-3,5-octanedionate (FOD). An example of a ketoiminate is 2-iso-propylimino-4-pentanonate. Examples of silanoates include tri-tert-butylsiloxide and triethylsiloxide. An example of a carboxylate is 2-ethylhexanoate.

Examples of D ligands include tetrahydrofuran, diethylether, 1,2-dimethoxyethane, diglyme, triglyme, tetraglyme, 12-Crown-6, 10-Crown-4, pyridine, N-methylpyrolidine, triethylamine, trimethylamine, acetonitrile, and 2,2-dimethylpropionitrile.

Representative examples of Group IlIl alkaline earth precursors include:

Be precursors: Be(N(SiMe₃)₂)₂, Be(TMPD)₂, and BeEt₂.

Mg precursors: Mg(N(SiMe₃)₂)₂, Mg(TMPD)₂, Mg(PrCp)₂, Mg(EtCp)₂, and MgCp₂.

Ca precursors: Ca(N(SiMe₃)₂)₂, Ca(i-Pr₄Cp)₂, and Ca(Me₅Cp)₂.

Sr precursors: Bis(tert-butylacetamidinato)strontium (TBAASr), Sr-C, Sr-D, Sr(N(SiMe₃)₂)₂, Sr(THD)₂, Sr(THD)₂(tetraglyme), Sr(iPr₄Cp)₂, Sr(iPr₃Cp)₂, and Sr(Me₅Cp)₂.

Ba precursors: Bis(tert-butylacetamidinato)barium (TBAABa), Ba-C, Ba-D, Ba(N(SiMe₃)₂)₂, Ba(THD)₂, Ba(THD)₂(tetraglyme), Ba(ⁱPr4Cp)₂, Ba(Me₅Cp)₂, and Ba(nPrMe₄Cp)₂.

Representative examples of Group IlIl precursors include: Hf(Ot-Bu)₄ (hafnium tert-butoxide, HTB), Hf(NEt₂)₄ (tetrakis(diethylamido)hafnium, TDEAH), Hf(NEtMe)₄ (tetrakis(ethylmethylamido)hafnium, TEMAH), Hf(NMe₂)₄ (tetrakis(dimethylamido)hafnium, TDMAH), Zr(Ot-Bu)₄ (zirconium tert-butoxide, ZTB), Zr(NEt₂)₄ (tetrakis(diethylamido)zirconium, TDEAZ), Zr(NMeEt)₄ (tetrakis(ethylmethylamido)zirconium, TEMAZ), Zr(NMe₂)₄ (tetrakis(dimethylamido)zirconium, TDMAZ), Hf(mmp)₄, Zr(mmp)₄, Ti(mmp)₄, HfCl₄, ZrCl₄, TiCl₄, Ti(Ni—Pr₂)₄, Ti(Ni—Pr₂)₃, tris(N,N′-dimethylacetamidinato)titanium, ZrCp₂Me₂, Zr(t-BuCp)₂Me₂, Zr(Ni—Pr₂)₄, Ti(Oi-Pr)₄, Ti(Ot-Bu)₄ (titanium tert-butoxide, TTB), Ti(NEt₂)₄ (tetrakis(diethylamido)titanium, TDEAT), Ti(NMeEt)₄ (tetrakis(ethylmethylamido)titanium, TEMAT), Ti(NMe₂)₄ (tetrakis(dimethylamido)titanium, TDMAT), and Ti(THD)₃ (tris(2,2,6,6-tetramethyl-3,5-heptanedionato)titanium).

Embodiments of the inventions may utilize a wide variety of different rare earth precursors. For example, many rare earth precursors have the formula:

M L¹L²L³Dₓ

where M is a rare earth metal element selected from the group of scandium (Sc), yttrium (Y), lutetium (Lu), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), and ytterbium (Yb). L¹, L², L³ are individual anionic ligands, and D is a neutral donor ligand where x can be 0, 1, 2, or 3. Each L¹, L², L³ ligand may be individually selected from the groups of alkoxides, halides, aryloxides, amides, cyclopentadienyls, alkyls, silyls, amidinates, β-diketonates, ketoiminates, silanoates, and carboxylates. D ligands may be selected from groups of ethers, furans, pyridines, pyroles, pyrolidines, amines, crown ethers, glymes, and nitriles.

Examples of L groups and D ligands are identical to those presented above for the alkaline earth precursor formula.

Representative examples of rare earth precursors include:

Y precursors: Y(N(SiMe₃)₂)₃, Y(N(i-Pr)₂)₃, Y(N(t-Bu)SiMe₃)₃, Y(TMPD)₃, Cp₃Y, (MeCp)₃Y, ((n-Pr)Cp)₃Y, ((n-Bu)Cp)₃Y, Y(OCMe₂CH₂NMe₂)₃, Y(THD)₃, Y[OOCCH(C₂H₅)C₄H₉]₃, Y(C₁₁H₁₉O₂)₃CH₃(OCH₂CH₂)₃OCH₃, Y(CF₃COCHCOCF₃)₃, Y(OOCC₁₀H₇)₃, Y(OOC₁₀H₁₉)₃, and Y(O(n-Pr))₃.

La precursors: La(N(SiMe₃)₂)₃, La(N(i-Pr)₂)₃, La(N(t-Bu)SiMe₃)₃, La(TMPD)₃, ((i-Pr)Cp)₃La, Cp₃La, Cp₃La(NCCH₃)₂, La(Me₂NC₂H₄CP)₃, La(THD)₃, La[OOCCH(C₂H₅)C₄H₉]₃, La(C₁₁H₁₉O₂)₃.CH₃(OCH₂CH₂)₃OCH₃, La(C₁₁H₁₉O₂)₃.CH₃(OCH₂CH₂)₄OCH₃, La(O(i-Pr))₃, La(OEt)₃, La(acac)₃, La(((t-Bu)₂N)₂CMe)₃, La(((i-Pr)₂N)₂CMe)₃, La(((t-Bu)₂N)₂C(t-Bu))₃, La(((i-Pr)₂N)₂C(t-Bu))₃, and La(FOD)₃.

Ce precursors: Ce(N(SiMe₃)₂)₃, Ce(N(i-Pr)₂)₃, Ce(N(t-Bu)SiMe₃)₃, Ce(TMPD)₃, Ce(FOD)₃, ((i-Pr)Cp)₃Ce, Cp₃Ce, Ce(Me₄Cp)₃, Ce(OCMe₂CH₂NMe₂)₃, Ce(THD)₃, Ce[OOCCH(C₂H₅)C₄H₉]₃, Ce(C₁₁ H₁₉O₂)₃.CH₃(OCH₂CH₂)₃OCH₃, Ce(C₁₁H₁₉O₂)₃.CH₃(OCH₂CH)₄OCH₃, Ce(O(i-Pr))₃, and Ce(acac)₃.

Pr precursors: Pr(N(SiMe₃)₂)₃, ((i-Pr)Cp)₃Pr, Cp₃Pr, Pr(THD)₃, Pr(FOD)₃, (C₅Me₄H)₃Pr, Pr[OOCCH(C₂H₅)C₄H₉]₃, Pr(C₁₁H₁₉O₂)₃.CH₃(OCH₂CH₂)₃OCH₃, Pr(O(i-Pr))₃, Pr(acac)₃, Pr(hfac)₃, Pr(((t-Bu)₂N)₂CMe)₃, Pr(((i-Pr)₂N)₂CMe)₃, Pr(((t-Bu)₂N)₂C(t-Bu))₃, and Pr(((i-Pr)₂N)₂C(t-Bu))₃.

Nd precursors: Nd(N(SiMe₃)₂)₃, Nd(N(i-Pr)₂)₃, ((i-Pr)Cp)₃Nd, Cp₃Nd, (C₅Me₄H)₃Nd, Nd(THD)₃, Nd[OOCCH(C₂H₅)C₄H₉]₃, Nd(O(i-Pr))₃, Nd(acac)₃, Nd(hfac)₃, Nd(F₃CC(O)CHC(O)CH₃)₃, and Nd(FOD)₃.

Sm precursors: Sm(N(SiMe₃)₂)₃, ((i-Pr)Cp)₃Sm, Cp₃Sm, Sm(THD)₃, Sm[OOCCH(C₂H₅)C₄H₉]₃, Sm(O(i-Pr))₃, Sm(acac)₃, and (C₅Me₅)₂Sm.

Eu precursors: Eu(N(SiMe₃)₂)₃, ((i-Pr)Cp)₃Eu, Cp₃Eu, (Me₄Cp)₃Eu, Eu(THD)₃, Eu[OOCCH(C₂H₅)C₄H₉]₃, Eu(O(i-Pr))₃, Eu(acac)₃, and (C₅Me₅)₂Eu.

Gd precursors: Gd(N(SiMe₃)₂)₃, ((i-Pr)Cp)₃Gd, Cp₃Gd, Gd(THD)₃, Gd[OOCCH(C₂H₅)C₄H₉]₃, Gd(O(i-Pr))₃, and Gd(acac)₃.

Tb precursors: Tb(N(SiMe₃)₂)₃, ((i-Pr)Cp)₃Tb, Cp₃Tb, Tb(THD)₃, Tb[OOCCH(C₂H₅)C₄H₉]₃, Tb(O(i-Pr))₃, and Tb(acac)₃.

Dy precursors: Dy(N(SiMe₃)₂)₃, ((i-Pr)Cp)₃Dy, Cp₃Dy, Dy(THD)₃, Dy[OOCCH(C₂H₅)C₄H₉]₃, Dy(O(i-Pr))₃, Dy(0₂C(CH₂)₆CH₃)₃, and Dy(acac)₃.

Ho precursors: Ho(N(SiMe₃)₂)₃, ((i-Pr)Cp)₃Ho, Cp₃Ho, Ho(THD)₃, Ho[OOCCH(C₂H₅)C₄H₉]₃, Ho(O(i-Pr))₃, and Ho(acac)₃.

Er precursors: Er(N(SiMe₃)₂)₃, ((i-Pr)Cp)₃Er, ((n-Bu)Cp)₃Er, Cp₃Er, Er(THD)₃, Er[OOCCH(C₂H₅)C₄H₉]₃, Er(O(i-Pr))₃, and Er(acac)₃.

Tm precursors: Tm(N(SiMe₃)₂)₃, ((i-Pr)Cp)₃Tm, Cp₃Tm, Tm(THD)₃, Tm[OOCCH(C₂H₅)C₄H₉]₃, Tm(O(i-Pr))₃, and Tm(acac)₃.

Yb precursors: Yb(N(SiMe₃)₂)₃, Yb(N(i-Pr)₂)₃, ((i-Pr)Cp)₃Yb, Cp₃Yb, Yb(THD)₃, Yb[OOCCH(C₂H₅)C₄H₉]₃, Yb(O(i-Pr))₃, Yb(acac)₃, (C₅Me₅)₂Yb, Yb(hfac)₃, and Yb(FOD)₃.

Lu precursors: Lu(N(SiMe₃)₂)₃, ((i-Pr)Cp)₃Lu, Cp₃Lu, Lu(THD)₃, Lu[OOCCH(C₂H₅)C₄H₉]₃, Lu(O(i-Pr))₃, and Lu(acac)₃.

In the above precursors, as well as precursors set forth below, the following common abbreviations are used: Si: silicon; Me: methyl; Et: ethyl; i-Pr: isopropyl; n-Pr: n-propyl; Bu: butyl; t-Bu: tert-butyl; Cp: cyclopentadienyl; THD: 2,2,6,6-tetramethyl-3,5-heptanedionate; TMPD: 2,2,6,6-tetramethylpiperidide; acac: acetylacetonate; hfac: hexafluoroacetylacetonate; and FOD: 6,6,7,7,8,8,8-heptafluoro-2,2-dimethyl-3,5-octanedionate.

Embodiments of the invention may utilize a wide variety of silicon precursors (silicon-containing gases) for incorporating silicon into the metal-silicon-containing films. Examples of silicon precursors include, but are not limited to, Si(OR)₄, where R may be a methyl group or a ethyl group, for example Si(OCH₂CH₃)₄), Si(OCH₃)₄, Si(OCH₃)₂(OCH₂CH₃)₂, Si(OCH₃)(OCH₂CH₃)₃, and Si(OCH₃)₃(OCH₂CH₃). Other silicon precursors silane (SiH₄), disilane (Si₂H₆), monochlorosilane (SiClH₃), dichlorosilane (SiH₂Cl₂), trichlorosilane (SiHCl₃), hexachlorodisilane (Si₂Cl₆), diethylsilane (Et₂SiH₂), and alkylaminosilane compounds. Examples of alkylaminosilane compounds include, but are not limited to, di-isopropylaminosilane (H₃Si(NPr₂)), bis(tert-butylamino)silane ((C₄H₉(H)N)₂SiH₂), tetrakis(dimethylamino)silane (Si(NMe₂)₄), tetrakis(ethylmethylamino)silane (Si(NEtMe)₄), tetrakis(diethylamino)silane (Si(NEt₂)₄), tris(dimethylamino)silane (HSi(NMe₂)₃), tris(ethylmethylamino)silane (HSi(NEtMe)₃), tris(diethylamino)silane (HSi(NEt₂)₃), and tris(dimethylhydrazino)silane (HSi(N(H)NMe₂)₃), bis(diethylamino)silane (H₂Si(NEt₂)₂), bis(di-isopropylamino)silane (H₂Si(NPr₂)₂), tris(isopropylamino)silane (HSi(NPr₂)₃), and (di-isopropylamino)silane (H₃Si(NPr₂).

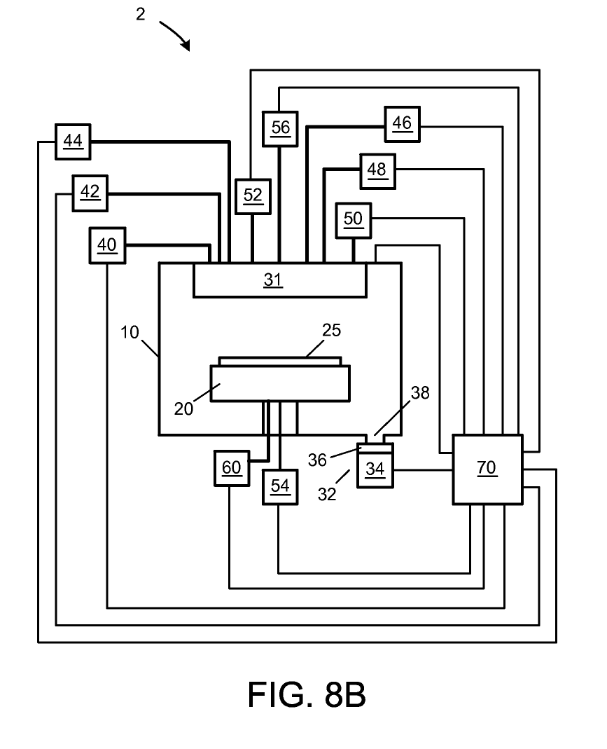

FIGS. 8A and 8B show simplified block diagrams of pulsed CVD systems for depositing metal-silicon-containing films on a substrate according to embodiments of the invention. In FIG. 8A, the pulsed CVD system 1 includes a process chamber 10 having a substrate holder 20 configured to support a substrate 25, upon which the metal-silicon-containing film is formed. The process chamber 10 further contains an upper assembly 30 (e.g., a showerhead) coupled to a first process material supply system 40, a second process material supply system 42, a purge gas supply system 44, an oxygen-containing gas supply system 46, a nitrogen-containing gas supply system 48, and an silicon-containing gas supply system 50. Additionally, the pulsed CVD system 1 includes a substrate temperature control system 60 coupled to substrate holder 20 and configured to elevate and control the temperature of substrate 25. Furthermore, the pulsed CVD system 1 includes a controller 70 that can be coupled to process chamber 10, substrate holder 20, upper assembly 30 configured for introducing process gases into the process chamber 10, first process material supply system 40, second process material supply system 42, purge gas supply system 44, oxygen-containing gas supply system 46, nitrogen-containing gas supply system 48, silicon-containing gas supply system 50, and substrate temperature control system 60.

Alternatively, or in addition, controller 70 can be coupled to one or more additional controllers/computers (not shown), and controller 70 can obtain setup and/or configuration information from an additional controller/computer.

In FIG. 8A, singular processing elements (10, 20, 30, 40, 42, 44, 46, 48, 50, and 60) are shown, but this is not required for the invention. The pulsed CVD system 1 can include any number of processing elements having any number of controllers associated with them in addition to independent processing elements.

The controller 70 can be used to configure any number of processing elements (10, 20, 30, 40, 42, 44, 46, 48, 50, and 60), and the controller 70 can collect, provide, process, store, and display data from processing elements. The controller 70 can comprise a number of applications for controlling one or more of the processing elements. For example, controller 70 can include a graphic user interface (GUI) component (not shown) that can provide easy to use interfaces that enable a user to monitor and/or control one or more processing elements.

Still referring to FIG. 8A, the pulsed CVD system 1 may be configured to process 200 mm substrates, 300 mm substrates, or larger-sized substrates. In fact, it is contemplated that the deposition system may be configured to process substrates, wafers, or LCDs regardless of their size, as would be appreciated by those skilled in the art. Therefore, while aspects of the invention will be described in connection with the processing of a semiconductor substrate, the invention is not limited solely thereto. Alternately, a pulsed batch CVD system capable of processing multiple substrates simultaneously may be utilized for depositing the metal-silicon-containing films described in the embodiments of the invention.

The first process material supply system 40 and the second process material supply system 42 may be configured for introducing metal-containing gases to the process chamber 10. According to embodiments of the invention, several methods may be utilized for introducing the metal-containing gases to the process chamber 10. One method includes vaporizing one or more metal-containing liquid precursors through the use of separate bubblers or direct liquid injection systems, or a combination thereof, and then mixing the vaporized one or more metal-containing liquid precursors in the gas phase within or prior to introduction into the process chamber 10. By controlling the vaporization rate of each precursor separately, a desired metal element stoichiometry can be attained within the deposited film. Another method of delivering multiple metal-containing precursors includes separately controlling two or more different liquid sources which are then mixed prior to entering a common vaporizer. This method may be utilized when the precursors are compatible in solution or in liquid form and they have similar vaporization characteristics. Other methods include the use of compatible mixed solid or liquid precursors within a bubbler. Liquid source precursors may include neat liquid rare earth precursors, or solid or liquid metal containing precursor solvents include, but are not limited to, ionic liquids, hydrocarbons (aliphatic, olefins, and aromatic), amines, esters, glymes, crown ethers, ethers and polyethers. In some cases it may be possible to dissolve one or more compatible solid precursors in one or more compatible liquid precursors. It will be apparent to one skilled in the art that a plurality of different metal elements may be included in this scheme by including a plurality of metal-containing precursors within the deposited film. It will also be apparent to one skilled in the art that by controlling the relative concentration levels of the various precursors within a gas pulse, it is possible to deposit mixed metal-silicon-containing films with desired stoichiometries.

Still referring to FIG. 8A, the purge gas supply system 44 is configured to introduce a purge gas to process chamber 10. For example, the introduction of purge gas may occur between the introduction of pulses of silicon-containing precursors to the process chamber 10. The purge gas can comprise an inert gas, such as a noble gas (i.e., He, Ne, Ar, Kr, Xe), nitrogen (N₂), or hydrogen (H₂).

Still referring to FIG. 8A, the oxygen-containing gas supply system 46 is configured to introduce an oxygen-containing gas (oxidizer gas) to the process chamber 10. The oxygen-containing gas can include oxygen (02), water (H₂O), or hydrogen peroxide (H₂O₂), or a combination thereof, and optionally an inert gas such as Ar. Similarly, the nitrogen-containing gas supply system 48 is configured to introduce a nitrogen-containing gas to the process chamber 10. The nitrogen-containing gas can include ammonia (NH₃), hydrazine (N₂H₄), C₁-C₁₀ alkylhydrazine compounds, or a combination thereof, and optionally an inert gas such as Ar. Common C₁ and C₂ alkylhydrazine compounds include monomethyl-hydrazine (MeNHNH₂), 1,1-dimethyl-hydrazine (Me₂NNH₂), and 1,2-dimethyl-hydrazine (MeNHNHMe).

According to one embodiment of the invention, the oxygen-containing gas or the nitrogen-containing gas can include an oxygen- and nitrogen-containing gas, for example NO, NO₂, or N₂O, or a combination thereof, and optionally an inert gas such as Ar.

Furthermore, pulsed CVD system 1 includes substrate temperature control system 60 coupled to the substrate holder 20 and configured to elevate and control the temperature of substrate 25. Substrate temperature control system 60 comprises temperature control elements, such as a cooling system including a re-circulating coolant flow that receives heat from substrate holder 20 and transfers heat to a heat exchanger system (not shown), or when heating, transfers heat from the heat exchanger system. Additionally, the temperature control elements can include heating/cooling elements, such as resistive heating elements, or thermoelectric heaters/coolers, which can be included in the substrate holder 20, as well as the chamber wall of the process chamber 10 and any other component within the pulsed CVD system 1. The substrate temperature control system 60 can, for example, be configured to elevate and control the substrate temperature from room temperature to approximately 350° C. to 550° C. Alternatively, the substrate temperature can, for example, range from approximately 150° C. to 350° C. It is to be understood, however, that the temperature of the substrate is selected based on the desired temperature for causing thermal decomposition of a particular metal-containing gas and silicon-containing gas on the surface of a given substrate on order to deposit a metal-silicon-containing film.

In order to improve the thermal transfer between substrate 25 and substrate holder 20, substrate holder 20 can include a mechanical clamping system, or an electrical clamping system, such as an electrostatic clamping system, to affix substrate 25 to an upper surface of substrate holder 20. Furthermore, substrate holder 20 can further include a substrate backside gas delivery system configured to introduce gas to the back-side of substrate 25 in order to improve the gas-gap thermal conductance between substrate 25 and substrate holder 20. Such a system can be utilized when temperature control of the substrate is required at elevated or reduced temperatures. For example, the substrate backside gas system can comprise a two-zone gas distribution system, wherein the helium gas gap pressure can be independently varied between the center and the edge of substrate 25.

Furthermore, the process chamber 10 is further coupled to a pressure control system 32, including a vacuum pumping system 34 and a valve 36, through a duct 38, wherein the pressure control system 32 is configured to controllably evacuate the process chamber 10 to a pressure suitable for forming the thin film on substrate 25. The vacuum pumping system 34 can include a turbo-molecular vacuum pump (TMP) or a cryogenic pump capable of a pumping speed up to about 5000 liters per second (and greater) and valve 36 can include a gate valve for throttling the chamber pressure. Moreover, a device for monitoring chamber pressure (not shown) can be coupled to the process chamber 10. The pressure measuring device can be, for example, a Type 628B Baratron absolute capacitance manometer commercially available from MKS Instruments, Inc. (Andover, Mass.). The pressure control system 32 can, for example, be configured to control the process chamber pressure between about 0.1 Torr and about 100 Torr during deposition of the metal-silicon-containing film.

The first process material supply system 40, the second process material supply system 42, the purge gas supply system 44, the oxygen-containing gas supply system 46, the nitrogen-containing gas supply system 48, and the silicon-containing gas supply system 50 can include one or more pressure control devices, one or more flow control devices, one or more filters, one or more valves, or one or more flow sensors. The flow control devices can include pneumatic driven valves, electro-mechanical (solenoidal) valves, and/or high-rate pulsed gas injection valves.

Still referring to FIG. 8A, controller 70 can comprise a microprocessor, memory, and a digital I/O port capable of generating control voltages sufficient to communicate and activate inputs to the pulsed CVD system 1 as well as monitor outputs from the pulsed CVD system 1. Moreover, the controller 70 may be coupled to and may exchange information with the process chamber 10, substrate holder 20, upper assembly 30, first process material supply system 40, second process material supply system 42, purge gas supply system 44, oxygen-containing gas supply system 46, nitrogen-containing gas supply system 48, silicon-containing gas supply system 50, substrate temperature control system 60, substrate temperature control system 60, and pressure control system 32. For example, a program stored in the memory may be utilized to activate the inputs to the aforementioned components of the pulsed CVD system 1 according to a process recipe in order to perform a deposition process.

However, the controller 70 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, resides software for controlling the controller 70, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the pulsed CVD system 1, or it may be remotely located relative to the pulsed CVD system 1. For example, the controller 70 may exchange data with the pulsed CVD system 1 using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the pulsed CVD system 1 via a wireless connection.

FIG. 8B illustrates a pulsed plasma-enhanced CVD (PECVD) system 2 for depositing a metal-silicon-containing film on a substrate according to an embodiment of the invention. The pulsed PECVD system 2 is similar to the pulsed CVD system 1 described in FIG. 8A, but further includes a plasma generation system configured to generate a plasma during at least a portion of the gas exposures in the process chamber 10. This allows formation of ozone and plasma excited oxygen from an oxygen-containing gas containing O₂, H₂O, H₂O₂, or a combination thereof. Similarly, plasma excited nitrogen may be formed from a nitrogen gas containing N₂, NH₃, or N₂H₄, or a combination thereof, in the process chamber. Also, plasma excited oxygen and nitrogen may be formed from a process gas containing NO, NO₂, and N₂O, or a combination thereof. The plasma generation system includes a first power source 52 coupled to the process chamber 10, and configured to couple power to gases introduced into the process chamber 10. The first power source 52 may be a variable power source and may include a radio frequency (RF) generator and an impedance match network, and may further include an electrode through which RF power is coupled to the plasma in process chamber 10. The electrode can be formed in the upper assembly 31, and it can be configured to oppose the substrate holder 20. The impedance match network can be configured to optimize the transfer of RF power from the RF generator to the plasma by matching the output impedance of the match network with the input impedance of the process chamber, including the electrode, and plasma. For instance, the impedance match network serves to improve the transfer of RF power to plasma in process chamber 10 by reducing the reflected power. Match network topologies (e.g. L-type, π-type, T-type, etc.) and automatic control methods are well known to those skilled in the art.

Alternatively, the first power source 52 may include a RF generator and an impedance match network, and may further include an antenna, such as an inductive coil, through which RF power is coupled to plasma in process chamber 10. The antenna can, for example, include a helical or solenoidal coil, such as in an inductively coupled plasma source or helicon source, or it can, for example, include a flat coil as in a transformer coupled plasma source.

Alternatively, the first power source 52 may include a microwave frequency generator, and may further include a microwave antenna and microwave window through which microwave power is coupled to plasma in process chamber 10. The coupling of microwave power can be accomplished using electron cyclotron resonance (ECR) technology, or it may be employed using surface wave plasma technology, such as a slotted plane antenna (SPA), as described in U.S. Pat. No. 5,024,716, entitled “Plasma processing apparatus for etching, ashing, and film-formation”; the contents of which are herein incorporated by reference in its entirety.

According to one embodiment of the invention, the pulsed PECVD system 2 includes a substrate bias generation system configured to generate or assist in generating a plasma (through substrate holder biasing) during at least a portion of the alternating introduction of the gases to the process chamber 10. The substrate bias system can include a substrate power source 54 coupled to the process chamber 10, and configured to couple power to the substrate 25. The substrate power source 54 may include a RF generator and an impedance match network, and may further include an electrode through which RF power is coupled to substrate 25. The electrode can be formed in substrate holder 20. For instance, substrate holder 20 can be electrically biased at a RF voltage via the transmission of RF power from a RF generator (not shown) through an impedance match network (not shown) to substrate holder 20. A typical frequency for the RF bias can range from about 0.1 MHz to about 100 MHz, and can be 13.56 MHz. RF bias systems for plasma processing are well known to those skilled in the art. Alternatively, RF power is applied to the substrate holder electrode at multiple frequencies. Although the plasma generation system and the substrate bias system are illustrated in FIG. 8B as separate entities, they may indeed comprise one or more power sources coupled to substrate holder 20.

In addition, the pulsed PECVD system 2 includes a remote plasma system 56 for providing and remotely plasma exciting an oxygen-containing gas, a nitrogen-containing gas, or a combination thereof, prior to flowing the plasma excited gas into the process chamber 10 where it is exposed to the substrate 25. The remote plasma system 56 can, for example, contain a microwave frequency generator.

### Example

### Deposition of Hafnium Silicate Films

Hafnium silicate films with thicknesses of approximately 8 nm were deposited on 300 mm silicon substrates using HTB gas, O₂ gas, and TEOS gas. The substrate was maintained at a temperature of 500° C. and the deposition times were about 300 seconds. O₂ gas flow was 100 sccm. The TEOS gas was delivered to the process chamber without the use of a carrier gas using vapor draw of TEOS liquid which has a vapor pressure of 2 mm Hg at 20° C. Argon dilution gas was added to the TEOS gas before the process chamber. Silicon-content of the relatively thick hafnium silicate films was determined using X-ray Photoelectron Spectroscopy (XPS) and calculated as (Si/(Si+Hf))×100%, where Hf is the amount of the hafnium metal (Hf atoms per unit volume) and Si is the amount of silicon (Si atoms per unit volume).

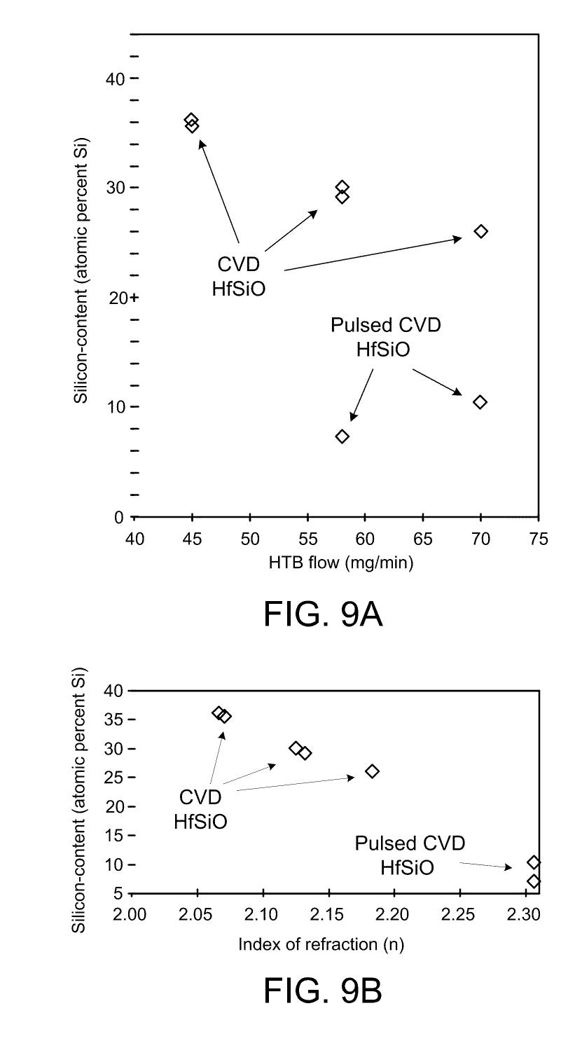

FIG. 9A shows silicon-content in CVD and pulsed CVD hafnium silicate films as a function of HTB gas flow according to embodiments of the invention. The silicon-content of the CVD hafnium silicate films was about 36% Si, about 30% Si, and about 26% Si, using HTB flows of 45 mg/min, 58 mg/min, and 70 mg/min, respectively. A mass flow controller used to deliver the HTB flow to the process chamber had an upper delivery limit of approximately 90 mg/min.

The TEOS gas flow during the CVD process was 0.1 sccm which was the lowest TEOS gas flow obtainable by the mass flow controller used. FIG. 9A shows that conventional CVD processing for depositing hafnium silicate films for semiconductor manufacturing using HTB gas, O₂ gas, and TEOS results in films with silicon-content greater than approximately 25% Si.

FIG. 9A further shows silicon-content in pulsed CVD hafnium silicate films. The pulsed CVD processing was performed using a continuous flow of HTB gas and O₂ gas, and using 30 TEOS pulses with TEOS pulse lengths of 5 seconds and TEOS pulse delays of 5 seconds. The TEOS flow in each TEOS pulse was 0.1 sccm. A HTB flow of 70 mg/min resulted in a hafnium silicate film with a silicon-content of 10.4% Si and a HTB flow of 58 mg/min resulted in a hafnium silicate film with a silicon-content of 7.2% Si. The results in FIG. 9A show that pulsed CVD processing according to embodiments of the invention can provide hafnium silicate films with much lower silicon-content than conventional CVD processing.

Deposition times between about 30 seconds and about 120 seconds are often desired for depositing thin films in a semiconductor manufacturing environment and therefore the film deposition rate must be low enough to enable good control and repeatability of the film thickness. For example, a 1.7 nm thick hafnium silicate film with silicon-content less than about 20% Si or less than about 10% Si, may be deposited in about 40 seconds using four TEOS pulses with a pulse length of 5 seconds and a pulse delay of 5 seconds.

FIG. 9B shows silicon-content in CVD and pulsed CVD hafnium silicate films as a function of index of refraction according to embodiments of the invention. Deposition conditions for the hafnium silicate films were described above for FIG. 9A. The results in FIG. 9B show that pulsed CVD processing according to embodiment of the invention can provide hafnium silicate films with higher index of refraction than conventional CVD processing.

A plurality of embodiments for depositing metal-silicon-containing films with low silicon-content for manufacturing of semiconductor devices has been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A method for forming a metal-silicon-containing film on a substrate, comprising:
providing the substrate in a process chamber;
maintaining the substrate at a temperature suited for chemical vapor deposition of the metal-silicon-containing film by thermal decomposition of a metal-containing gas and a silicon-containing gas on the substrate;
exposing the substrate to a continuous flow of the metal-containing gas; and
during the continuous flow, exposing the substrate to sequential pulses of the silicon-containing gas.

2. The method of claim 1, wherein the metal-containing gas is exposed to the substrate without interruption from a period of time before a first pulse of the silicon-containing gas.

3. The method of claim 1, wherein the metal-containing gas is exposed to the substrate without interruption from a period of time after a last pulse of the silicon-containing gas.

4. The method of claim 1, wherein the metal-containing gas is exposed to the substrate without interruption from a period of time before a first pulse of the silicon-containing gas to a period of time after a last pulse of the silicon-containing gas.

5. The method of claim 1, wherein a gas flow rate of the silicon-containing gas increases in consecutive pulses.

6. The method of claim 1, wherein a gas flow rate of the silicon-containing gas decreases in consecutive pulses.

7. The method of claim 1, wherein a gas flow rate of the silicon-containing gas increases in consecutive pulses and thereafter the gas flow rate of the silicon-containing gas decreases in consecutive pulses.

8. The method of claim 1, wherein a gas flow rate of the silicon-containing gas decreases in consecutive pulses and thereafter the gas flow rate of the silicon-containing gas increases in consecutive pulses.

9. The method of claim 1, wherein pulse duration of the silicon-containing gas increases in consecutive pulses.

10. The method of claim 1, wherein pulse duration of the silicon-containing gas decreases in consecutive pulses.

11. The method of claim 1, wherein pulse duration of the silicon-containing gas increases in consecutive pulses and thereafter the pulse duration decreases in consecutive pulses.

12. The method of claim 1, wherein pulse duration of the silicon-containing gas decreases in consecutive pulses and thereafter the pulse duration increases in consecutive pulses.

13. The method of claim 1, wherein the metal-containing gas comprises a Group II precursor, a Group III precursor, or a rare earth precursor, or a combination thereof.

14. The method of claim 1, wherein the metal-containing gas comprises a hafnium-precursor, a zirconium-precursor, or both a hafnium-precursor and a zirconium-precursor, and the metal-silicon-containing film comprises a hafnium silicate film, a zirconium silicate film, or a hafnium zirconium silicate film.

15. The method of claim 1, wherein the silicon-containing gas comprises Si(OCH₂CH₃)₄, Si(OCH₃)₄, Si(OCH₃)₂(OCH₂CH₃)₂, Si(OCH₃)(OCH₂CH₃)₃, Si(OCH₃)₃(OCH₂CH₃), SiH₄, Si₂H₆, SiClH₃, SiH₂Cl₂, SiHCl₃, Si₂Cl₆, Et₂SiH₂, H₃Si(NPr₂), (C₄H₉(H)N)₂SiH₂, Si(NMe₂)₄, Si(NEtMe)₄, Si(NEt₂)₄, HSi(NMe₂)₃, HSi(NEtMe)₃, HSi(NEt₂)₃, HSi(N(H)NMe₂)₃, H₂Si(NEt₂)₂, H₂Si(NPr₂)₂, HSi(NPr₂)₃, or H₃Si(NPr₂), or a combination of two or more thereof.

16. The method of claim 1, wherein the metal-silicon-containing film has a silicon-content that is less than 20 atomic percent silicon.

17. The method of claim 1, wherein the metal-silicon-containing film has a silicon-content that is less than 10 atomic percent silicon.

18. The method of claim 1, wherein the continuous flow further comprises an oxidizer gas.

19. A method for forming a metal silicate film on a substrate, comprising:
providing the substrate in a process chamber;
maintaining the substrate at a temperature suited for chemical vapor deposition of the metal silicate film by thermal decomposition of a metal-containing gas and a molecular silicon-oxygen-containing gas on the substrate;
exposing the substrate to a continuous flow of the metal-containing gas; and
during the continuous flow, exposing the substrate to sequential pulses of the molecular silicon-oxygen-containing gas.

20. The method of claim 19, wherein the metal silicate film comprises a hafnium silicate film, a zirconium silicate film, or a hafnium zirconium silicate film.

21. The method of claim 20, wherein the metal-containing gas comprises Hf(Ot-Bu)₄ gas, Zr(Ot-Bu)₄ gas, or a combination thereof, and the molecular silicon-oxygen-containing gas comprises Si(OCH₂CH₃)₄ gas.

22. The method of claim 19, wherein the metal silicate film has a silicon-content that is less than 20% silicon.

23. The method of claim 19, wherein the metal silicate film has a silicon-content that is less than 10% silicon.

24. The method of claim 19, wherein the metal-containing gas is exposed to the substrate without interruption from a period of time before a first pulse of the molecular silicon-oxygen-containing gas to a period of time after a last pulse of the molecular silicon-oxygen-containing gas.

25. A method for forming a hafnium silicate film on a substrate, comprising:
providing the substrate in a process chamber;
maintaining the substrate at a temperature suited for chemical vapor deposition of the hafnium silicate film by thermal decomposition of a Hf(Ot-Bu)₄ gas and a Si(OCH₂CH₃)₄ gas on the substrate;
exposing the substrate to a continuous flow of the Hf(Ot-Bu)₄ gas;
exposing the substrate to a continuous flow of O₂ gas; and
during the continuous flows, exposing the substrate to sequential pulses of the Si(OCH₂CH₃)₄ gas, wherein the hafnium silicate film has a silicon-content that is less than 20% silicon.
